(19) United States
(12) Patent Application Publication
(10) Pub. No.: US 2018/0309090 A1
(43) Pub. Date: Oct. 25, 2018

(54) ORGANIC LIGHT-EMITTING DIODE WITH EFFICIENCY OPTIMIZED BY PLASMON SUPPRESSION

(71) Applicant: COMMISSARIAT A L'ENERGIE ATOMIQUE ET AUX ENERGIES ALTERNATIVES, Paris (FR)

(72) Inventors: Salim BOUTAMI, GRENOBLE (FR); Stéphane GETIN, GRENOBLE (FR); Tony MAINDRON, GRENOBLE (FR); Benoit RACINE, BEVENAIS (FR)

(21) Appl. No.: 15/957,789

(22) Filed: Apr. 19, 2018

(30) Foreign Application Priority Data
Apr. 25, 2017 (FR) 1753567

(51) Int. Cl. H01L 51/52

(52) U.S. Cl. CPC H01L 51/5275; H01L 51/5265; H01L 51/5271

(57) ABSTRACT

An organic light-emitting diode comprises a first electrode, a stack of semiconducting organic layers, comprising at least one light-emitting organic layer, deposited on top of the first electrode and a second electrode deposited on a surface of the stack opposite the first electrode, wherein the first electrode comprises at least one region in electrical contact with the stack of semiconducting organic layers surrounded by one or more regions electrically insulated from the stack, each electrically insulated region structured to form at least one Bragg mirror adapted to reflect plasmons with a wavelength λ of emission from the light-emitting layer and guided by an interface between the first electrode and the stack of semiconducting organic layers, each region in electrical contact with the stack forming, with the Bragg mirror or mirrors surrounding it, a cavity not supporting any resonant plasmon mode at the wavelength λ. A method for fabricating such an organic light-emitting diode is provided.

### CROSS-REFERENCE TO RELATED APPLICATIONS

his application claims priority to foreign French patent application No. FR 1753567, filed on Apr. 25, 2017, the disclosure of which is incorporated by reference in its entirety.

### FIELD OF THE INVENTION

The invention relates to an organic light-emitting diode (OLED), more particularly of the top emission type. Such a diode can be applied, in particular, to display (OLED screens), but also lends itself to other applications such as lighting.

### BACKGROUND

An OLED is composed of a stack of semiconducting organic layers comprising at least one emissive layer, situated between two electrodes, very often metallic. The organic stack is composed of at least one hole transport layer, one emission layer (light-emitting) and an electron transport layer. The thickness of the organic zone is generally set around 100 nm, so as to form a half-wave Fabry-Pérot cavity for the visible (the optical index of the organic layers is typically of the order of 1.7). The application of a potential difference between the electrodes injected into the organic stack of electrons and holes which recombine radiatively in the emissive layer.

The emitters have a fairly short electrode distance with respect to the wavelength, which generates the excitation of plasmons on the surface of the electrodes, in addition to the useful radiative vertical Fabry-Pérot mode. These plasmons are planar guided modes, totally absorbed by the metal at the end of a certain lateral propagation distance.

The document WO 2014/191733 describes an organic light-emitting diode with top emission (that is to say through the surface opposite that of the substrate), in which the top electrode, through which the light is emitted, is structured periodically so as to form a diffraction grating. The document US 2013/0153861, for its part, describes an organic light-emitting diode with bottom emission (that is to say through the substrate) in which it is the bottom electrode which is structured. In both cases, the coupling with the grating makes it possible—in a way that is known per se—to extract the plasmons, thus improving the radiative efficiency.

This approach makes it possible to extract a part of the energy of the plasmons, but not to completely eliminate the losses associated therewith. Furthermore, in the case of a top emission diode (WO 2014/191733), the structuring of the top electrode risks degrading the organic stack.

### SUMMARY OF THE INVENTION

The invention aims to overcome the drawbacks of the prior art. More particularly, it aims to procure an organic light-emitting diode, notably with top emission, exhibiting a radiative efficiency that is optimized by suppression of at least a part of the losses due to the plasmon modes.

In accordance with the invention, this aim is achieved by structuring the bottom electrode so as to define planar cavities delimited by electrically insulated Bragg mirrors. Only the cavities are in electrical contact with the semiconducting organic stack, whereas the regions of the electrode forming the Bragg mirrors are insulated. Consequently, it is only at the cavities that plasmons can be excited. The Bragg mirrors which delimit the cavities are dimensioned so as to exhibit a high reflectivity at the wavelength of the plasmons; thus, the latter cannot be propagated and can therefore exist only in the form of resonant standing modes, localized in the cavities—but on the condition that the geometry (size and form) of the latter permits. The cavities can in particular have dimensions, related to a wavelength of emission of the diode, such that no standing mode can exist at said wavelength: the excitation of the plasmons is therefore suppressed, which very greatly reduces the losses and therefore increases the radiative efficiency. The counterpart of this increase in efficiency is a reduction of the active surface (that is to say the surface capable of emitting light) of the OLED, because the light emission occurs only in connection with the cavities. That is, however, not an issue for many applications, given the low cost of fabrication of the OLEDs and their very high level of brightness.

A subject of the invention is therefore an organic light-emitting diode comprising a first electrode, a stack of semiconducting organic layers, comprising at least one light-emitting organic layer, deposited on top of said first electrode and a second electrode deposited on a surface of said stack opposite said first electrode, characterized in that said first electrode comprises at least one region in electrical contact with the stack of semiconducting organic layers surrounded by one or more regions electrically insulated from said stack, said or each said electrically insulated region being structured so as to form at least one Bragg mirror adapted to reflect plasmons at a wavelength λ of emission of said light-emitting layer and guided by an interface between said first electrode and said stack of semiconducting organic layers, said or each said region in electrical contact with the stack forming, with the Bragg mirror or mirrors surrounding it, a cavity not supporting any resonant plasmon mode at said wavelength λ.

According to particular embodiments of such an organic light-emitting diode:
Said or each said Bragg mirror can be formed by etching grooves hollowed out in the surface of said first electrode and filled with a dielectric material.
Said regions of the first electrode electrically insulated from the stack of semiconducting organic layers can be covered with a layer of dielectric material.
Said or each said Bragg mirror can be a spatially periodic structure comprising a number of periods of between 2 and 5.
Said or each said Bragg mirror can be a spatially periodic structure of a period equal to λ/2n_{eff}, in which λ is a wavelength of emission of said light-emitting organic layer and n_{eff} an effective refractive index seen by said plasmons.
The spatially periodic structure forming said or each said Bragg mirror can have a fill factor of between 30% and 70%, preferably between 40% and 60% and even more preferably between 45% and 55%.
Said or each said region in electrical contact with the stack of semiconducting organic layers can have at least one dimension equal to

$$W = m \cdot \frac{λ}{4 {n}_{eff}} - \frac{ϕ \cdot λ}{2 π {n}_{eff}} ,$$

in which n_{eff} is an effective refractive index seen by said plasmons, φ a phase shift introduced by the Bragg mirror or mirrors and m an odd integer strictly greater than 1. More particularly, the value of m can be chosen from 3, 5 and 7.
The diode can also comprise a dielectric encapsulation layer or multilayer structure deposited on top of said second electrode, and a dielectric layer having a structuring forming a diffraction grating deposited on top of said dielectric encapsulation layer or multilayer structure.

Another subject of the invention is a method for fabricating such an organic light-emitting diode comprising:

a step of structuring of a metallic layer constituting said first electrode, so as to form said or each said Bragg mirror;

a step of covering said or each said Bragg mirror with a dielectric layer; and

a step of deposition of said stack of semiconducting organic layers on top of said first electrode, and of the second electrode on a surface of said stack opposite said first electrode.

According to particular embodiments of such a method:
Said step of structuring of the first electrode can be performed by etching grooves in the surface of said electrode; and said step of covering said or each said Bragg mirror with a dielectric layer can comprise: the deposition of said dielectric layer on all the surface of the electrode, so as to fill said grooves, then a selective etching of said layer so as to free at least one region intended to be in electrical contact with said stack of semiconducting organic layers.
The method can also comprise, before said step of deposition of said stack of semiconducting organic layers and of the second electrode, a step of planarization of said dielectric layer.

### BRIEF DESCRIPTION OF THE DRAWING

Other features, details and advantages of the invention will emerge on reading the description given with reference to the attached drawings given by way of example and which represent, respectively:

FIG. 1, an OLED according to the prior art;

FIGS. 2A and 2B, 2C, OLEDs having a bottom electrode structured so as to form cavities whose geometry allows (2A, 2C) or does not allow (2B) the excitation of standing plasmon modes;

FIGS. 3A and 3B, two examples of planar geometries of cavities according to respective embodiments of the invention;

FIG. 4, a graph of the radiative efficiency of an OLED according to an embodiment of the invention as a function of a characteristic dimension of one said cavity;

FIG. 5, a graph of the radiative efficiency of an OLED according to an embodiment of the invention as a function of the wavelength; and

FIG. 6, an OLED according to an embodiment of the invention, having a bottom electrode structured so as to form cavities having a geometry adapted to prevent the excitation of standing plasmon modes, and a structured dielectric layer allowing the extraction of the plasmons guided by the top electrode.

### DETAILED DESCRIPTION

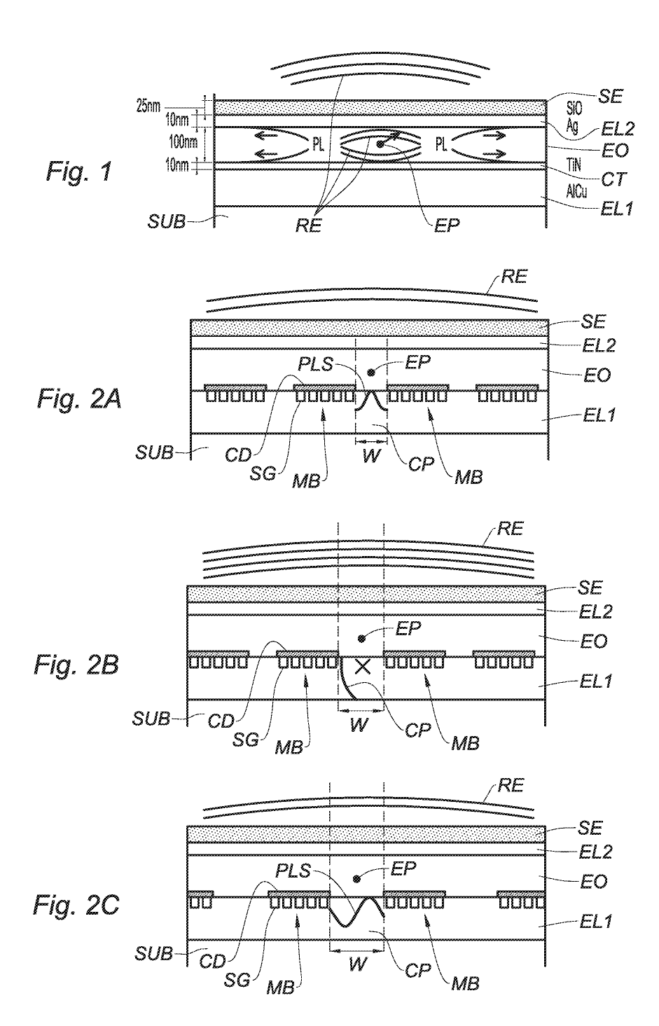

The organic light-emitting diode of FIG. 1 (which is not to scale) comprises, starting from the bottom:
A substrate SUB, which can be, for example, of silicon or glass.
A bottom electrode EL1, made of AlCu alloy, deposited (for example by Physical Vapour Deposition—PVD) on top of a surface of the substrate. This electrode is opaque and can be relatively thick (several hundreds of nanometres, even a few micrometres).
A buffer layer CT made of TiN, having a thickness of the order of 10 nm, deposited for example by PVD, PECVD (Plasma-Enhanced Chemical Vapour Deposition) or ALD (Atomic Layer Deposition).
An organic stack EO, 100 nm thick, obtained for example by PVD or liquid phase deposition. At the centre of this stack there is a light-emitting layer, exhibiting an emission centred at the wavelength of 550 nm. The figure does not show this layer, but only a spot emitter (one point of the layer) EP, used in the calculations allowing the optimization of the efficiency of the OLED. The reference RE represents the light radiation emitted by the spot emitter and that is propagated in a direction substantially normal to the surface of the substrate. The reference PL denotes the plasmons guided by the interfaces between the organic stack and the bottom and top electrodes. The invention aims to prevent the excitation of the plasmons on the surface of the top electrode, and therefore to eliminate the losses introduced thereby.
A top electrode EL2, deposited on top of the organic stack, of Ag and having a thickness of 10 nm—sufficiently small to be substantially transparent.
An encapsulation structure SE covering the top electrode in order to protect the organic stack from the atmospheric oxygen and more generally from any contamination. In the device of FIG. 1, this encapsulation structure is composed of a layer of SiOₓ (x≤2), fabricated for example by PVD, having a thickness of 25 nm. Other embodiments can comprise more powerful multilayer encapsulation structures. For example it may be advantageous to provide, on top of the layer of SiO₂, a second layer of TiO₂ produced by atomic layer deposition (ALD) that can have a thickness as small as 5 nm. Such a layer, highly compact, substantially improves the seal-tightness of the encapsulation.

The OLED of FIG. 2A is differentiated from that of FIG. 1 only in that the bottom electrode EL1 is structured. More specifically, the surface of said electrode in contact with the organic stack EO comprises structured regions MB which surround non-structured regions CP. The structured regions MB contain etching grooves SG, with a depth of a few tens of nanometres (typically between 20 nm and 200 nm and preferably of the order of 100 nm, the latter value being used in the simulations discussed hereinbelow), evenly spaced apart so as to form a periodic pattern and filled with a dielectric material—typically a resin or SiO₂. A dielectric layer CD (typically composed of the same material which fills the grooves SG) separates these structured regions MB from the organic stack EO; thus, the injection of the carriers is done only in connection with the non-structured regions CP. In FIG. 2A, and in FIGS. 2B and 2C, the buffer layer CT is not represented—it can be considered to be merged with the surface of the electrode EU; at the structured regions, it is covered by the dielectric layer CD.

The periodicity L of the etching grooves SG is chosen so as to satisfy the Bragg condition for a wavelength λ of emission of the light-emitting layer of the OLED (for example, the central wavelength, or that corresponding to the emission peak), that is to say

$$L = \frac{λ}{2 \cdot {n}_{eff}}$$

in which n_{eff} is an effective refractive index for the plasmons, dependent mainly on the refractive indices of the organic layers (generally of a value close to but greater than that of the indices of these layers). Preferentially, the widths of the grooves and their spacings have values close to

$$\frac{λ}{4 \cdot {n}_{eff}} ,$$

which corresponds to a fill factor (grooves/spacing between grooves ratio) of the order of 50%. More generally, the fill factor can be between 30% and 70%, preferably between 40% and 60% and even more preferably between 45% and 55%.

Thus, these regions MB form Bragg mirrors reflecting the plasmons generated at the interface between the stack EO and the bottom electrode EL1. These mirrors are all the more reflecting when the number of periods—that is to say the number of grooves—that they include is higher; however, the higher this number, the smaller the active fraction (that is to say the fraction capable of injecting carriers into the light-emitting layer) of the electrode, and therefore the weaker the brightness of the OLED will be. One acceptable trade-off consists in choosing Bragg mirrors comprising between 2 and 5 periods.

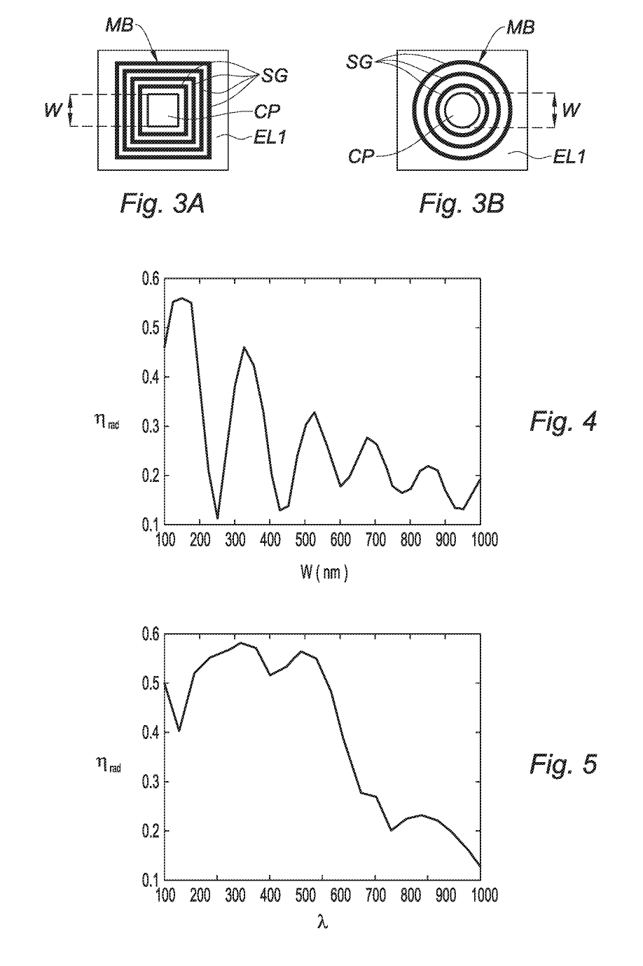

FIG. 2A is a cross-sectional view and does not show the two-dimensional configuration of the structured and non-structured regions. FIGS. 3A and 3B illustrate two possible configurations among others. In the case of FIG. 3A, the etching grooves follow concentric square lines; in that of FIG. 3B, they form concentric circles. In both cases, the structured regions MB completely surround a non-structured region CP. The latter therefore behaves as a cavity, that is to say a resonator, for the plasmons.

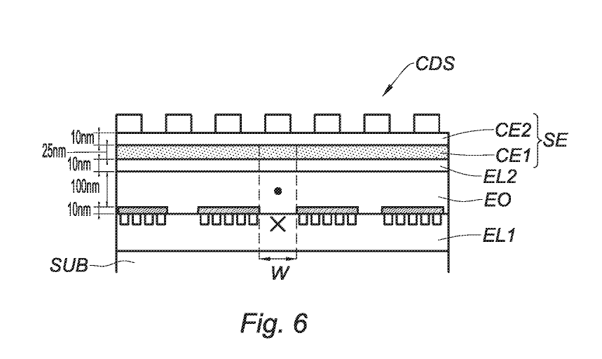

In FIGS. 2A-2C and 6, the dimensional relationships between the cavities CP and the structured regions MB are not observed.

In the device of FIG. 2A, the width W of the cavity CP (the length of its side in the case of a square geometry—FIG. 3A—or of its diameter in the case of a circular geometry—FIG. 3B) is equal, for a value of the wavelength λ belonging to the spectrum of emission of the light-emitting layer of the OLED (for example, the central wavelength, or that corresponding to the emission peak; preferably, it is the same wavelength used for the dimensioning of the spatial period L), at

$$\frac{λ}{2 {n}_{eff}} - \frac{ϕ λ}{2 π {n}_{eff}}$$

in which φ represents a phase-shift introduced by the Bragg mirrors, which depends on the structure; hereinafter it will be assumed, by way of nonlimiting example, that φ=π/2 which gives

$$W = \frac{λ}{4 {n}_{eff}} .$$

That means that a standing plasmon mode PLS (more specifically, a fundamental mode, or first order mode) of wavelength λ satisfies a resonance condition and can therefore be excited and survive in the cavity. In these conditions, significant losses are observed, as in the case of a non-structured electrode. FIG. 2B relates to the case where

$$W = \frac{3 \cdot λ}{4 \cdot {n}_{eff}} - \frac{ϕλ}{2 π {n}_{eff}} = \frac{λ}{2 \cdot {n}_{eff}}$$

(by taking φ=π/2) for said wavelength λ. In these conditions, no standing mode PLS of wavelength λ satisfies a resonance condition of the cavity. The excitation of the plasmons is therefore suppressed, and the efficiency of the OLED at the wavelength λ increases.

FIG. 2C relates to the case where

$$W = \frac{λ}{{n}_{eff}} - \frac{ϕλ}{2 π {n}_{eff}} = \frac{3 \cdot λ}{4 \cdot {n}_{eff}}$$

(by taking φ=π/2). In these conditions, a standing plasmon mode PLS of wavelength λ can once again be excited; it is then a second order resonant mode. Here again, this plasmon mode introduces losses.

When the width W of the cavity is subsequently increased, the excitation of the plasmons is once again suppressed before the third order plasmon mode becomes resonant in its turn, and so on. It can therefore be expected that the radiative efficiency, defined as the ratio between the radiated power P_{rad} and the sum of this same radiated power and of the power P_{abs} absorbed by the metallic electrodes (losses due mainly to the plasmons):

$${η}_{rad} = \frac{{P}_{rad}}{{P}_{rad} + {P}_{abs}}$$

oscillates as a function of the width W of the cavity. That is confirmed by FIG. 4 which is a graph, obtained by digital simulation, of the radiative efficiency of the OLED of FIGS. 2A-2C, at a wavelength of 550 nm, as a function of the cavity width W.

It can be verified that the optimum efficiency is achieved for W≅150 nm, which is consistent with the theory set out above, and corresponds to the configuration of FIG. 2B, by considering an effective refractive index of the order of 1.65, λ=550 nm and φ=π/2. In these optimum conditions, the efficiency is approximately 60%, whereas, in the absence of structuring (which corresponds to the limit W→∞) it does not even reach 11%. When W exceeds this optimum value, the efficiency decreases to a minimum for W≅250 nm, which corresponds to the configuration of FIG. 2C. Beyond, the efficiency oscillates, each minimum corresponding to the appearance of a new resonance mode of the cavity.

Generally, the efficiency maxima correspond to widths

$$W = m \cdot \frac{λ}{4 {n}_{eff}} - \frac{ϕ \cdot λ}{2 π {n}_{eff}}$$

with m an odd integer greater than 1 (m=3, 5, 7 . . . ) and the efficiency minima correspond to the widths

$$W = m \cdot \frac{λ}{4 {n}_{eff}} - \frac{ϕ \cdot λ}{2 π {n}_{eff}}$$

with m an even integer greater than 0 (m=2, 4, 6 . . . ).

The position of the minima and of the maxima depend on the phase φ, but, by contrast their separation is always λ/4n_{eff}.

It will be noted that the maxima and the minima are increasingly less pronounced as the width W increases, because there is a tendency toward the “classic” situation in which the electrode is continuous and of great dimensions relative to the wavelength. Thus, m=3 or 5, even at the very most 7, will preferably be used.

For the very low values of W, the theory set out with reference to FIGS. 2A-2C is no longer valid: the width of the cavity becomes smaller than the thickness of the OLED and the useful vertical Fabry-Pérot resonance is no longer retained. Consequently, the efficiency plummets. For this reason, FIG. 4 does not take into consideration widths less than 100 nm.

FIG. 5 illustrates the radiative efficiency of the photodiode of FIG. 2B (W=150 nm, corresponding to the first maximum of FIG. 4). Although the dimensioning is performed by considering a single wavelength, λ=550 nm, it will be noted that the increase of efficiency occurs over a wide band. The average efficiency integrated over all the visible range (400-700 nm) amounts to 40%, which is considerable. The dependence of the efficiency of the wavelength depends in particular on the Bragg mirror structure used; in particular, the phase-shift introduced by a Bragg mirror can vary in complex ways, and not necessarily symmetrically, as a function of λ.

An OLED according to the invention can be fabricated by a conventional method, to which are added the steps of structuring of the bottom electrode (and of the buffer layer covering it) prior to the deposition of the organic stack EO.

These steps comprise the production of the grooves SG by reactive ion etching (RIE), the deposition of a dielectric layer which covers the bottom electrode and fills the grooves, then the selective removal—for example by photoetching—of this dielectric layer so as to free the cavities.

Preferably, there is then a planarization, for example chemical-mechanical (CMP, Chemical-Mechanical Planarization). Next, the stack EO is deposited on top of the structured electrode in a perfectly conventional way, the top electrode is deposited on top of the stack and the structure is encapsulated to protect it from oxygen and moisture.

The planarization step is not essential, because any irregularities of the dielectric layer CD will affect only passive regions (without injection of carriers) of the stack EO.

The structuring of the bottom electrode, in accordance with the invention, has no effect on the plasmons which are propagated at the interface between the stack EO and the top electrode, and which also contribute to the losses. Furthermore, losses are also provoked by guided optical modes which remain trapped in the OLED. These losses can, in principle, be reduced by structuring the top electrode, as taught by the abovementioned document WO 2014/191733. However, the structuring of the top electrode risks degrading the underlying organic stack. A more promising solution, illustrated by FIG. 6, consists in depositing, on top of the encapsulation structure SE, a dielectric layer CDS, for example of Al₂O₃ deposited by ALD, and in structuring it so as to form a diffraction grating.

The CDS layer is responsible for the extraction of the plasmons and of the guided modes in the organic stack; for that, the period L of its structuring is given by:

$$L = \frac{λ}{{n}_{eff}^{′}}$$

in which λ is the wavelength of the spectral band of emission of the OLED (typically, the central wavelength) and n′eff is an effective refractive index, whose value (generally different from n_{eff}) is dominated by that of the index of the encapsulation structure. Digital computations make it possible to verify that the radiative efficiency is maximized when the peak-valley amplitude of the structuring is of the order of 100 nm or more and its fill factor is approximately 50% (for example between 30% and 70%, or, preferably, between 40% and 60%, or even more preferably between 45% and 55%).

Advantageously, the structuring is obtained by etching the CDS layer—for example by reactive ion etching—over all its depth. That requires the presence of an etch stop layer. To this end, it is advantageous to use a more complex encapsulation structure than that considered hitherto, comprising a first layer CE1 of SiO₂, for example 25 nm thick, on which is deposited a second layer CE2 of TiO₂ 5 nm thick obtained by atomic layer deposition (ALD). The second layer CE2 serves as etch stop layer for the CDS layer and, as has already been stated above, improves the seal-tightness of the encapsulation.

The invention has been described primarily with reference to the embodiment of FIG. 2B, but numerous variants are possible.

The organic stack, the second electrode and the encapsulation structure are conventional elements and can be modified in a known way.

The bottom electrode serves generally as cathode and the top electrode as anode, but the reverse is also possible.

The thicknesses of the different layers are not critical.

The arrangement of the etching grooves may not be perfectly periodic, provided that it remains sufficiently reflective. Moreover, the grooves are only one example of structure that can be formed on the surface of the electrode. In another embodiment, they could be replaced, for example, by overthicknesses protruding from the surface.

The cavities can have more complex forms than those illustrated in FIGS. 3A and 3B. What counts, is that they cannot support any plasmon mode at at least one wavelength of emission of the light-emitting layer of the OLED.

1. An organic light-emitting diode comprising a first electrode, a stack of semiconducting organic layers, comprising at least one light-emitting organic layer, deposited on top of said first electrode and a second electrode deposited on a surface of said stack opposite said first electrode, wherein said first electrode comprises at least one region in electrical contact with the stack of semiconducting organic layers surrounded by one or more regions electrically insulated from said stack, said or each said electrically insulated region being structured so as to form at least one Bragg mirror adapted to reflect plasmons at a wavelength λ of emission from said light-emitting layer and guided by an interface between said first electrode and said stack of semiconducting organic layers, said or each said region in electrical contact with the stack forming, with the Bragg mirror or mirrors surrounding it, a cavity not supporting any resonant plasmon mode at said wavelength λ.

2. The organic light-emitting diode according to claim 1, wherein each said Bragg mirror is formed by etching grooves, hollowed out in the surface of said first electrode and filled with a dielectric material.

3. The organic light-emitting diode according to claim 1, wherein said regions of the first electrode electrically insulated from the stack of semiconducting organic layers are covered with a layer of dielectric material.

4. The organic light-emitting diode according to claim 1, wherein each said Bragg mirror is a spatially periodic structure comprising a number of periods of between 2 and 5.

5. The organic light-emitting diode according to claim 1, wherein each said Bragg mirror is a spatially periodic structure of a period equal to λ/2n_{eff} in which λ is a wavelength of emission of said light-emitting organic layer and n_{eff} an effective refractive index seen by said plasmons.

6. The organic light-emitting diode according to claim 5, wherein the spatially periodic structure forming said or each said Bragg mirror exhibits a fill factor of between 30% and 70%, preferably between 40% and 60% and even more preferably between 45% and 55%.

7. The organic light-emitting diode according to claim 1, wherein each said region in electrical contact with the stack of semiconducting organic layers has at least one dimension equal to
$$W = m \cdot \frac{λ}{4 {n}_{eff}} - \frac{ϕ \cdot λ}{2 π {n}_{eff}}$$
in which n_{eff} is an effective refractive index seen by said plasmons, φ a phase-shift introduced by the Bragg mirror or mirrors and m an odd integer strictly greater than 1.

8. The organic light-emitting diode according to claim 7, wherein the value of m is chosen from 3, 5 and 7.

9. The organic light-emitting diode according to claim 1 also comprising a dielectric encapsulation layer or multilayer structure deposited on top of said second electrode, and a dielectric layer having a structuring forming a diffraction grating deposited on top of said dielectric encapsulation layer or multilayer structure.

10. A method for fabricating an organic light-emitting diode according to claim 1, comprising:
a step of structuring of a metallic layer constituting said first electrode, so as to form said or each said Bragg mirror;
a step of covering said or each said Bragg mirror with a dielectric layer; and
a step of deposition of said stack of semiconducting organic layers on top of said first electrode and the second electrode on a surface of said stack opposite said first electrode.

11. The method according to claim 10, wherein:
said step of structuring of said first electrode is performed by etching grooves in the surface of said electrode;
said step of covering said or each said Bragg mirror with a dielectric layer comprises: the deposition of said dielectric layer on all the surface of the electrode, so as to fill said grooves, then a selective etching of said layer so as to free at least one region intended to be in electrical contact with said stack of semiconducting organic layers.

12. The method according to claim 11, also comprising, before said step of deposition of said stack of semiconducting organic layers and of the second electrode, a step of planarization of said dielectric layer.
